(19) United States
(12) Patent Application Publication
(10) Pub. No.: US 2013/0220410 A1
(43) Pub. Date: Aug. 29, 2013

(54) Precursors for Photovoltaic Passivation

(71) Applicants: Mary Kathryn Haas, Emmaus, PA (US); Anupama Mallikarjunan, Macungie, PA (US); Robert Gordon Ridgeway, Quakertown, PA (US); Katherine Anne Hutchison, Sunnyvale, CA (US); Michael T. Savo, Bethlehem, PA (US)

(72) Inventors: Mary Kathryn Haas, Emmaus, PA (US); Anupama Mallikarjunan, Macungie, PA (US); Robert Gordon Ridgeway, Quakertown, PA (US); Katherine Anne Hutchison, Sunnyvale, CA (US); Michael T. Savo, Bethlehem, PA (US)

(73) Assignee: Air Products and Chemicals, Inc., Allentown, PA (US)

(21) Appl. No.: 13/595,419

(22) Filed: Aug. 27, 2012

Related U.S. Application Data
(60) Provisional application No. 61/531,749, filed on Sep. 7, 2011.

(51) Int. Cl. H01L 31/0216

(52) U.S. Cl. CPC H01L 31/02167
USPC 136/256; 438/57

(57) ABSTRACT

Deposition methods are disclosed for producing a passivation layer on a photovoltaic cell. Method includes depositing a passivation layer comprising at least a bi-layer further comprising a silicon oxide and a silicon nitride layer. In one aspect, the silicon precursor(s) used for the deposition of the silicon oxide layer or the silicon nitride layer, respectively, is selected from the family SiRₓH_{y} or selected from the family SiRₓH, silane, and combinations thereof, wherein in SiRₓH_{y} x+y=4, y≠4 and R may be independently selected from the group consisting of C₁-C₈ linear alkyl, wherein the ligand may be saturated or unsaturated; C₁-C₈ branched alkyl, wherein the ligand may be saturated or unsaturated; C₁-C₈ cyclic alkyl, wherein the ligand may be saturated, unsaturated, or aromatic; and NR*₃ wherein R* can be independently hydrogen; or linear, branched, cyclic, saturated, or unsaturated alkyl. Photovoltaic devices containing the passivation layers are also disclosed.

### CROSS-REFERENCE TO RELATED APPLICATIONS

This application claims the benefit of U.S. Provisional Application No. 61/531,749 filed Sep. 7, 2011, the disclosure of which is incorporated by reference in its entirety.

### BACKGROUND OF THE INVENTION

The present invention is directed to the field of silicon-based dielectric materials produced by CVD methods. In particular, it is directed to methods for making films of such materials and their use as passivation or barrier coatings in photovoltaic devices.

Photovoltaic (“PV”) cells convert light energy into electrical energy. Many photovoltaic cells are fabricated using either monocrystalline silicon or multicrystalline silicon as substrates. The silicon substrates in the cells are commonly modified with a dopant of either positive or negative conductivity type, and are on the order of 50-500 microns in thickness. Throughout this application, the surface of the substrate, such as a wafer, intended to face incident light is designated as the front surface and the surface opposite the front surface is referred to as the back surface. By convention, positively doped silicon is commonly designated as “p”, where holes are the majority electrical carriers. Negatively doped silicon is designated as “n” where electrons are the majority electrical carrier. The key to the operation of a photovoltaic cell is the creation of a p-n junction, usually formed by further doping a thin layer at the front surface of the silicon substrate (FIG. 1). Such a layer is commonly referred to as the emitter layer, while the bulk silicon is referred to as the absorber layer. The emitter may be either p-doped or n-doped depending on the configuration of the device.

A key requirement for optimal photovoltaic device efficiency is effective passivation of the front and back surfaces of the silicon. The surface of any solid typically represents a large disruption from the crystal periodicity of the bulk, and thus generates a higher population of sub-stoichiometric bonding resulting in electrical defects. For silicon, when these defects occur energetically within the range of the band gap, they increase carrier recombination and negatively impact device efficiency. When the silicon surface is coated with a passivation layer (PL), the properties of the silicon-PL become critical. Again, the crystal periodicity of bulk silicon is interrupted due to the presence of non-silicon atoms at the interface.

Silicon-PL interface charge can play a critical role in influencing effectiveness of passivation. Fixed charge generated during PL deposition can create an induced field in the underlying silicon (Aberle, Progress in Photovoltaics, 8, 473). For a passivation layer in contact with n-type silicon, a high positive fixed charge is desired in order to decrease carrier recombination. For a passivation layer in contact with p-type silicon, a reduced positive fixed charge is desired in order to decrease carrier recombination and prevent parasitic shunting.

In addition to functioning as a passivation layer, the dielectric material may provide anti-reflective properties in order to reduce reflectivity and increase light absorption.

A process for making photovoltaic devices incorporating SiNxHy passivation is described by Leguijt and Wanka, (WO08043827A; Solar Energy Materials and Solar Cells, 40, 297) where the passivation layer is deposited using silane and ammonia). The process results in a high positive fixed charge at the interface of typically >+1e12/cm2. Therefore the process is compatible for passivation in contact with n-type silicon, but produces inferior results when in contact with p-type silicon (Dauwe, Progress in Photovoltaics, 10, 271).

A process for making photovoltaic devices incorporating thermally grown silicon oxide is described in US2009151784A. The process requires high temperatures in range of 800-1000 C and may result in slow processing times. The process is known to produce a fixed interface charge on the order of e11/cm2 which is compatible with passivation of p-type silicon surfaces.

A process for making photovoltaic devices incorporating chemically grown silicon oxide is also described by Naber, (34^{th} IEEE PVSC 2009. The process requires nitric acid treatment with potentially long immersion times.

A process for making photovoltaic devices incorporating CVD oxide/nitride stacked layers is described by Hofmann (Advances in Optoelectronics, 485467), using silane with N₂O, O₂, or ammonia. The process reports surface recombination velocities of 200 cm/sec after deposition and 60 cm/sec after firing at 800° C. for 3 seconds. The deposition of silane oxide films may require high plasma power density and deposition temperature due to the bond strength of Si—H present in the silane precursor.

Therefore, there is a need for depositing passivation films or layers using precursors that provide excellent interface properties in contact with p-type silicon, at deposition temperatures less than 450° C., with manufacturable throughput and cost of ownership. Optionally, a nitride film may be deposited on top of the oxide film (FIG. 2). The passivation layer may be present at the front side of the device, backside of the device, or both.

### BRIEF SUMMARY OF THE INVENTION

This invention relates to methods for producing a passivation layer for photovoltaic devices; and the photovoltaic devices thereof.

In one aspect, there is provided a method for depositing at least one passivation layer on a photovoltaic cell in a chamber comprising steps of:
providing the photovoltaic cell having a rear surface and a front surface;
providing a first silicon precursor;
providing an oxygen source;
depositing a silicon oxide layer having a thickness ranging from 5 to 70 nm at least on one surface of the photovoltaic cell;
providing a second silicon precursor;
providing a nitrogen source; and
depositing a silicon nitride layer having a thickness ranging from 20 to 200 nm on the silicon oxide layer;
wherein the passivation layer having a thickness ranging from 25 to 600 nm comprising at least one bi-layer comprising the silicon oxide layer and the silicon nitride layer.

In another aspect, there is provided a photovoltaic device comprising:
a photovoltaic cell comprising:
   a P-doped silicon layer adjacent a N-doped silicon layer,
   a rear surface and a front surface;
and
at least one passivation layer deposited on the photovoltaic cell by the disclosed method.

In yet another aspect, there is provided a photovoltaic device comprising:
a photovoltaic cell comprising
   a P-doped silicon layer adjacent a N-doped silicon layer,
   a rear surface and a front surface;
and
at least one passivation layer deposited on at least one of the surfaces of the photovoltaic cell;
wherein the passivation layer having at least one bi-layer consisting of a silicon oxide layer having a thickness ranging from 5 to 70 nm and a silicon nitride layer having a thickness ranging from 20 to 200 nm.

The silicon oxide layer and the silicon nitride layer in the passivation layer are deposited by using silicon precursors independently selected from family of SiRₓH_{y} for the silicon oxide layer; and from the group consisting of silane, the family of SiRₓH_{y}, and combinations thereof for the silicon nitride layer;

wherein x+y=4, y≠4, and R is independently selected from the group consisting of
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and NR*₃;
wherein R* can be independently selected from the group consisting of hydrogen; and linear, branched, cyclic, saturated, or unsaturated alkyl.

Examples of silicon precursors from the family of SiRₓH_{y} include but not limited to methylsilane, dimethylsilane, trimethylsilane, tetramethylsilane, ethylsilane, diethylsilane, tetraethylsilane, propylsilane, dipropylsilane, isobutylsilane, tertbutylsilane, dibutylsilane, methylethylsilane, dimethyldiethylsilane, methyltriethylsilane, ethyltrimethylsilane, isopropylsilane, diisopropylsilane, triisopropylsilane, disopropylaminosilane, aminosilane, diaminosilane, methylaminosilane, ethylaminosilane, diethylaminosilane, dimethylaminosilane, bis-tertbutylaminosilane, and bis-isopropylamino(methylvinylsilane).

### BRIEF DESCRIPTION OF SEVERAL VIEWS OF THE DRAWINGS

FIG. 1. Four representative photovoltaic device configurations illustrating the presence of passivation layer(s).

FIG. 2. Schematic of silicon oxide passivation layer coated with optional silicon nitride layer.

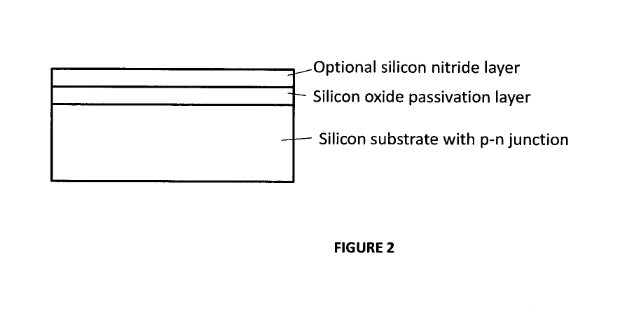

FIG. 3. Minority carrier lifetime as a function of minority carrier density for silicon passivated with triethylsilane oxide and a second layer of triethylsilane nitride.

### DETAILED DESCRIPTION OF THE INVENTION

The present invention relates to the deposition method for producing a passivation layer or film for photovoltaic devices.

The method comprises steps of:

providing the photovoltaic cell having a rear surface and a front surface;

providing a silicon precursor;

providing an oxygen source;

depositing a silicon oxide layer at least on one surface of the photovoltaic cell;

The silicon precursor is selected from the family of SiRₓH_{y};
wherein x+y=4, y≠4, and R is independently selected from the group consisting of
C1-C8 linear alkyl, where the ligand may be saturated or unsaturated; examples are methyl, ethyl, butyl, propyl, hexyl, ethylene, vinyl, allyl, 1-butylene, 2-butylene.
C1-C8 branched alkyl, where the ligand may be saturated or unsaturated; examples are isopropyl, isopropylene, isobutyl, tert-butyl.
C1-C8 cyclic alkyl, where the ligand may be saturated, unsaturated, or aromatic; examples are cyclopentyl, cyclohexyl, benzyl, methylcyclopentyl; and
NR*₃ where R*can be independently hydrogen; or linear, branched, cyclic, saturated, or unsaturated alkyl.
   wherein the passivation layer is a silicon oxide film.

Additional layers may optionally be deposited on top of the silicon oxide layer. For example, silicon nitride, silicon carbide, silicon carbonitride, transparent conductive oxide, aluminum oxide, amorphous silicon.

For example, a silicon nitride film (or layer) can deposited to cover the silicon oxide film (or layer) using the silicon precursor selected from the group consisting of silane, the family of SiRₓH_{y} SiRₓH_{y}; wherein x+y=4, y≠4, and R is independently selected from the group consisting of C1-C8 linear alkyl, wherein the ligand is saturated or unsaturated; C1-C8 branched alkyl, wherein the ligand may be saturated or unsaturated; C1-C8 cyclic alkyl, wherein the ligand may be saturated, unsaturated, or aromatic; NR*₃; wherein R*can be independently hydrogen; or linear, branched, cyclic, saturated, or unsaturated alkyl; and combinations thereof. In this case, the passivation layer is a bi-layer having both silicon oxide layer and silicon nitride layer.

For example, the passivation layer can be a bi-layer, wherein the silicon nitride layer is deposited by using silane and ammonia.

A passivation layer can also contain multiple bi-layers.

This invention also relates to a photovoltaic device comprising
a photovoltaic cell comprising:
   a P-doped silicon layer adjacent a N-doped silicon layer,
   a rear surface and a front surface;
and
at least one passivation layer deposited on at least one of the surfaces, using at least one silicon precursor selected from the family of SiRₓH_{y};
wherein x+y=4, y≠4, and R is independently selected from the group consisting of
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and
NR*₃; wherein R* can be independently selected from the group consisting of hydrogen; and linear, branched, cyclic, saturated, or unsaturated alkyl;
wherein the passivation layer is a silicon oxide film.

Optionally, each surface of the photovoltaic cell, that is, the surface of the P-doped silicon layer and the surface of the N-doped silicon layer has a passivation layer deposited on it.

The passivation layer can be a silicon oxide film, a bi-layer of a silicon oxide layer and a silicon nitride layer, or multiple bi-layers.

When silicon oxide/nitride bi-layer stack is utilized, it should be understood that the deposition precursor used for depositing the silicon oxide and silicon nitride layers may be the same precursor, or two distinct precursors.

It should be understood that the silicon oxide layer may include low concentrations of carbon and hydrogen. The concentration of carbon is preferably less than 5% atomic, and the concentration of hydrogen is preferably less than 20% atomic.

It should be understood that the silicon nitride layer may include low concentrations of carbon and oxygen. The concentration of carbon is preferably less than 5% atomic, and the concentration of oxygen is preferably less than 2% atomic.

It should be understood that the silicon nitride layer will contain a measurable concentration of hydrogen, consistent with amorphous films known in the art.

In one embodiment, a photovoltaic cell such as, for example, a photovoltaic cell according to the present invention is fabricated using a doped substrate comprising silicon, typically in the form of a wafer or a ribbon. The substrate can comprise monocrystalline silicon and multicrystalline silicon. As used herein, “silicon” includes monocrystalline silicon and multicrystalline silicon unless expressly noted. One or more layers of additional material; for example, germanium, may be disposed over the substrate surface or incorporated into the substrate if desired. Although boron is widely used as the p-type dopant, other p-type dopants such as, for example, gallium or indium, can also be employed. Although phorphorous is widely used as an n-type dopant, other dopants may be used. Thus, the photovoltaic cell, the silicon substrate or the substrate are exchangeable.

Silicon substrates are typically obtained by slicing silicon ingots, vapor phase deposition, liquid phase epitaxy or other known methods. Slicing can be via inner-diameter blade, continuous wire or other known sawing methods. Although the substrate can be cut into any generally flat shape, wafers are typically circular in shape. Generally, such wafers are typically less than about 500 micrometers thick. Preferably, substrates of the present invention are less than about 200 micrometers thick.

Before further processing, the substrate is preferably cleaned to remove any surface debris and cutting damage. Typically, this includes placing the substrate in a wet chemical bath such as, for example, a solution comprising any one of a base and peroxide mixture, an acid and peroxide mixture, a NaOH solution, or several other solutions known and used in the art. The temperature and time required for cleaning depends on the specific solution employed.

Optionally (especially for monocrystalline substrates), the substrate is texturized by, for example, anisotropic etching of the crystallographic planes. Texturing is commonly in the form of pyramid-shapes depressed or projected from the substrate surface. The height or depth of the pyramid-shapes varies with processing, but is typically from about 1 to about 7 micrometers. One or both sides of the solar cell may be textured.

An emitter layer is formed typically by doping the substrate with a dopant electrically opposite to that present in the bulk. N-doping can be accomplished by depositing the n-dopant onto the substrate and then heating the substrate to “drive” the n-dopant into the substrate. Gaseous diffusion can be used to deposit the n-dopant onto the substrate surface. Other methods can also be used, however, such as, for example, ion implantation, solid state diffusion, or other methods used in the art to create an n-doped layer and a shallow p-n junction proximal to the substrate surface. Phosphorus is a preferred n-dopant, but any suitable n-dopant can be used alone or in combination such as, for example, arsenic, antimony or lithium. Conversely, boron doping may be applied using similar methods. After emitter formation, a p-n junction is created along all exposed of the surfaces of the substrate. In some embodiments, it may be necessary to remove a doped region from one side or from the edges of the wafer during subsequent processing.

The emitter doping process may create a layer of silicon oxide on the exposed surfaces of the wafer, which is typically removed prior to application of a passivation coating. The silicon oxide can be removed through, for example, chemical etching in a wet chemical bath, typically a low concentration HF solution.

In one embodiment, local high density doping may then be performed in order to generate areas of selective emitters.

Prior to deposition of a passivation layer, the substrate may be cleaned using acidic or basic solutions known in the art.

The films depositions of the present invention are compatible with the various chemical processes used to produce photovoltaic devices, and are capable of adhering to a variety of materials. For example, the deposition is chemical vapor deposition (CVD) or plasma enhanced chemical vapor deposition (PECVD).

In the bi-layer embodiment, the silicon oxide layer is typically 5 to 70 nm in thickness, preferably 5 to 45; and the silicon nitride layer is typically 20 to 200, preferably 30 to 150 nm in thickness. The passivation films can have multiple bi-layers. The passivation layer of the present invention are deposited to a total thickness typically from about 25 to 600 nm, preferably, 40 to about 500 nm. The thickness can be varied as required, one bi-layer (the silicon oxide layer and the silicon nitride layer), and/or multiple bi-layer can be applied.

Preferably, the passivation films according to the present invention have a refractive index between 1.0 and 4.0 and, more preferably, between 1.7 and 2.3. Improved reflectivity over a range of wavelengths can be achieved with two or more films. For example, the more layers of the antireflective coating according to the present invention, the greater the range of wavelengths over which the reflectivity can be minimized. Typically with multiple layers, each layer will have a different refractive index.

Silicon precursors suitable for use in the present invention include but not limited to methylsilane, dimethylsilane, trimethylsilane, tetramethylsilane, ethylsilane, diethylsilane, triethylsilane, tetraethylsilane, propylsilane, dipropylsilane, isobutylsilane, tertbutylsilane, dibutylsilane, methylethylsilane, dimethyldiethylsilane, methyltriethylsilane, ethyltrimethylsilane, isopropylsilane, diisopropylsilane, triisopropylsilane, disopropylaminosilane, aminosilane, diaminosilane, methylaminosilane, ethylaminosilane, diethylaminosilane, dimethylaminosilane, bis-tertbutylaminosilane, and bis-isopropylamino(methylvinylsilane).

Deposition of the silicon oxide layer may utilize an oxygen source includes but not limited to O₂, N₂O, ozone, hydrogen peroxide, NO, NO₂, N₂O₄, or mixtures thereof.

Deposition of the silicon nitride layer may utilize an nitrogen source includes but not limited to NH₃, methylamine, dimethylamine, trimethylamine, or mixtures thereof.

Liquid precursors can be delivered to the reactor system by any number of means, preferably using a pressurized stainless steel vessel fitted with the proper valves and fittings to allow the delivery of liquid to the process reactor.

Additional materials can be charged into the vacuum chamber prior to, during and/or after the deposition reaction. Such materials include, e.g., inert gas (e.g., He, Ar, N₂, Kr, Xe, etc., which may be employed as a carrier gas for lesser volatile precursors) and reactive substances, such as gaseous or liquid organic substances, NH₃, and H₂.

Energy is applied to the gaseous reagents to induce the gases to react and to form the layer on the substrate. Such energy can be provided by (depending on the method employed), e.g., thermal, plasma, pulsed plasma, helicon plasma, high density plasma, inductively coupled plasma, and remote plasma methods. A secondary rf frequency source can be used to modify the plasma characteristics at the substrate surface. Preferably, the coating is formed by plasma enhanced chemical vapor deposition. The plasma frequency may range from 10 KHz to 40 MHz depending on the deposition system. The chamber configuration may be single or multi wafer, and direct or remote plasma.

The flow rate for each of the gaseous reagents preferably ranges from 10 to 10,000 sccm, and are highly dependent on the volume of the chamber. The flow rate for the silicon precursors preferably ranges from 10 sccm to 1700 sccm; the flow rate for the oxygen source preferably ranges from 500 to 17000 sccm; and the flow rate for the nitrogen source preferably ranges from 500 to 17000 sccm.

Front and back contacts are applied to the substrate using one of multiple known methods: photolithographic, laser grooving and electroless plating, screen printing, or any other method that provides good ohmic contact with the front and back surfaces respectively such that electric current can be drawn from the photovoltaic cell. Typically, the contacts are present in a design or pattern, for example a grid, fingers, lines, etc., and do not cover the entire front or back surface. After applying the contacts, the substrate may be fired (heat treatment), at a temperature of from about 800 to about 950° C. for 1-10 seconds, to anneal the contacts to the substrate. Methods for adding contacts to a wafer substrate for a photovoltaic cell are known in the art.

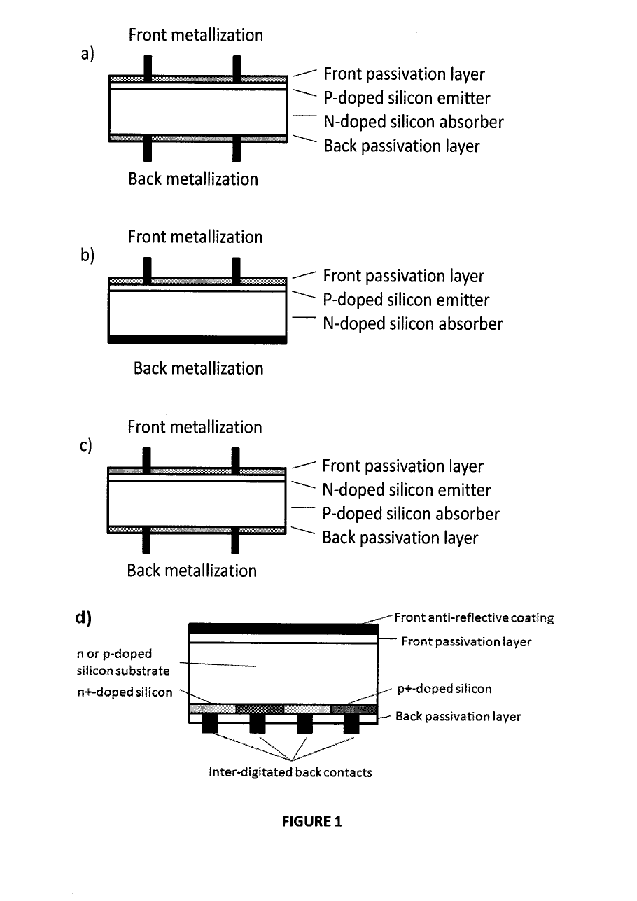

Four possible device configurations are presented in FIG. 1. The invention is compatible with devices where the p-n junction is formed at the front of the device (FIG. 1a, 1b, 1c).

The invention is also compatible with device configurations such as metal-wrap through contacts, interdigitated back contacts (FIG. 1d), or interdigitated front contacts. In these devices, the p-n junction is not formed homogeneously at the front of the device. However, an effective passivation layer remains critical to device performance.

Passivation layers generated using the present invention may provide the benefit of increased internal reflectance when used on the backside of a device, due to the influence of the film's refractive index on degree of Fresnel reflection over the full angular range. Increased internal reflection generally provides higher device efficiency.

Passivation layers generated using the present invention may provide an additional benefit of anti-reflection when used on the front side of the device. Optimization of layer thickness to refractive index can minimize the amount of light that is reflected away from the front side of the device. Decreased front reflectance generally leads to increased device efficiency.

Passivation layers generated using the present invention do not substantially degrade during firing at 800° C. for 4 seconds. Preferably, less than 20% reduction in surface lifetime occurs. More preferably, there is an improvement in surface carrier lifetime.

Passivation layers having one bi-layer stack, generated using the present invention provide surface recombination lifetime values of <200 cm/sec without firing and or annealing. More preferably, the films have surface recombination lifetimes of <100 cm/sec; and most preferably, the films have surface recombination lifetimes of <50 cm/sec, without firing and or annealing.

The invention will be illustrated in more detail with reference to the following Examples, but it should be understood that the present invention is not deemed to be limited thereto.

### EXAMPLES

Bond energy calculations were performed using the density functional based DmoI3 module of commercially available Materials Studio package.

For examples 1 to 4, depositions were performed on p-type Float Zone silicon substrates having a resistivity of 1000-2000 Ω-cm after a three step RCA cleaning to remove organic and metal surface impurities and HF surface treatment to remove native oxide.

For example 5, deposition was performed on p-type Float Zone silicon substrates having a resistivity of 1-5 Ω-cm.

Depositions were performed on both sides of the silicon substrate in order to allow measurement of surface recombination lifetime using a Sinton lifetime tester.

Depositions were performed on a 200 mm single wafer PECVD platform at 13.56 MHz. Deposition temperature for silicon oxide and silicon nitride ranged from 200-450° C.; preferably between 200 and 400° C. for silicon oxide; and between 300° C. and 450° C. for silicon nitride.

Chamber pressure for the depositions ranged from 2-10 torr. Electrode spacing ranged from 200-800 mil. Power ranged 300 to 1000 W.

For all examples, 15 nm of silicon oxide was deposited directly on the silicon substrate, and covered with 85 nm of silicon nitride.

### Example 1

Bond energies were calculated for silane, and several alkyl and amino silanes. In contrast to silane, the alkyl and amino substituted versions have ligands with lower thermodynamic bond energies. Not wishing to be bound by theory, it is hypothesized that the lower bond energies allow formation of a silicon oxide at lower plasma power densities and deposition temperature which provides enhanced passivation performance.

The calculated bond energies for silane and alkyl silane molecules were shown in Table 1.

TABLE 1
Calculated bond energies for silane and alkyl silane molecules

| | Si—H | Si—C | Si—N |
|---|---|---|---|
| Molecule | bond energy | bond energy | bond energy |
| Silane | 95 kcal/mole | N/A | N/A |
| Ethylsilane | 95 kcal/mole | 80 kcal/mole | N/A |
| Diethylsilane | 96 kcal/mole | 79 kcal/mole | N/A |
| Triethylsilane | 96 kcal/mole | 79 kcal/mole | N/A |
| Trimethylsilane | 97 kcal/mole | 87 kcal/mole | N/A |
| Tetramethylsilane | N/A | 86 kcal/mole | N/A |
| Diisoproylaminosilane | 93 kcal/mole | N/A | 80 kcal/mole |

### Example 2

Depositions were performed using the same silicon precursor to deposit the oxide and nitride layers. Lifetime data were collected using a Sinton lifetime tester in transient mode and recorded for minority carrier lifetime values of 1e¹⁵ and 5e¹⁴.

For silicon oxide layers, the deposition conditions were: 8 torr for chamber pressure; 500 mil for Electrode spacing; 800 W Power; 1000 sccm for O₂ flow rate; 1000 sccm for He flow rate; and the deposition temperatures were at 250 and 350° C.

For silicon nitride layers, the deposition conditions were: 3 torr for chamber pressure; 400 mil for Electrode spacing; 400 W Power; 225 sccm for NH₃ flow rate; 400 sccm for He flow rate; and the deposition temperature was at 350° C.

The flow rates for the silicon precursors were: 220 mg/min (42 sccm) and 125 mg/min (24 sccm) for triethylsilane; 250 mg/min (48 sccm) and 140 mg/min (23 sccm) for Diisopropylaminosilane; 350 mg/min (42 sccm) and 197 mg/min (27 sccm) for Bisisopropylamino-(vinylmethylsilane); for silicon oxide and silicon nitride layers respectively.

Minority carrier lifetime and surface recombination velocity for various passivation chemistries were shown in Table 2.

TABLE 2
Minority carrier lifetime and surface recombination velocity
(SRV) for various passivation chemistries

| | | | SRV | SRV |
|---|---|---|---|---|
| | Lifetime at | Lifetime at | at 5e14 | at 1e15 |
| Precursor | 5e14 MCD | 1e15 MCD | MCD | MCD |
| Triethylsilane | 1.8 millisec | 1.3 millisec | 13.2 | 19.2 |
| | | | cm/sec | cm/sec |
| Diisopropylaminosilane | 0.57 millisec | 0.34 millisec | 44.6 | 73.5 |
| | | | cm/sec | cm/sec |
| Bisisopropylamino- | 0.47 millisec | 0.28 millisec | 54.3 | 89.3 |
| (vinylmethylsilane) | | | cm/sec | cm/sec |

Lifetimes in the Table 2 represented an average of 2-8 experiments. Surface recombination velocity (SRV) was determined using the equation SRV=t/2(τ) where t is the silicon thickness in cm and τ is the measured lifetime in seconds. Each of the three precursors that use for deposition resulted in SRV values less than 100 cm/sec, in contrast to Hofman et al (Advances in Optoelectronics, 485467), who reported 700 cm/sec for bi-layer after deposition using monosilane for both silicon oxide and silicon nitride without heat treatments, such as, firing or/and annealing.

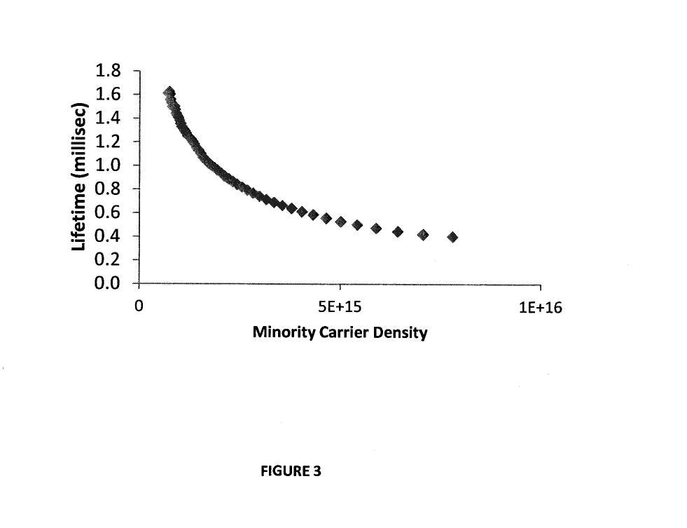

An example lifetime spectra for triethylsilane is plotted in FIG. 3.

### Example 3

An oxide layer was deposited using tetramethyl silane, followed by a nitride layer deposited using trimethyl silane.

The deposition temperatures was 350° C.; and the flow rates of tetramethyl silane was at 1200 mg/min (300 sccm), O₂ was at 1000 sccm, 3 torr and 800 W for the silicon oxide layers.

The deposition temperatures was 400° C. and the flow rates of trimethyl silane was at 80 mg/min(24 sccm), NH₃ was at 350 sccm; 3 torr; 400 W for the silicon nitride layer.

Minority carrier lifetime and surface recombination velocity for tetramethylsilane oxide passivation layer with a second layer of trimethylsilane nitride were shown in Table 3. Depositions resulted in SRV values of less than 100 cm/sec.

TABLE 3
Minority carrier lifetime and surface recombination velocity
for tetramethylsilane oxide passivation layer with
a second layer of trimethylsilane nitride

| | | | | SRV |
|---|---|---|---|---|
| | Lifetime at | Lifetime at | SRV at 5e14 | at 1e15 |
| Precursor | 5e14 MCD | 1e15 MCD | MCD | MCD |
| Tetramethylsilane/ | 1.2 millisec | 0.79 millisec | 20.8 cm/sec | 31.6 |
| trimethylsilane | | | | cm/sec |

### Example 4

Triethylsilane films from example 2 were heated using a belt furnace at a peak temperature of 800° C. for less than 10 seconds. The heat treatment which is typical of that experienced during screen print metallization, results in an improvement of approximately 20% in lifetime at an minority carrier density (MCD) value of 5e14.

Minority carrier lifetime and surface recombination velocity for triethylsilane passivation layer before and after heat treatment were shown in Table 4.

TABLE 4
Minority carrier lifetime and surface recombination velocity for
triethylsilane passivation layer before and after heat treatment

| | Lifetime at | Lifetime at | SRV at 5e14 | SRV at 1e15 |
|---|---|---|---|---|
| Precursor | 5e14 MCD | 1e15 MCD | MCD | MCD |
| Triethylsilane | 1.8 millisec | 1.3 millisec | 13.2 cm/sec | 19.2 cm/sec |
| before heating | | | | |
| Triethylsilane | 2.2 millisec | 1.7 millisec | 11.4 cm/sec | 14.7 cm/sec |
| after heating | | | | |

### Example 5

Depositions were performed using the same silicon precursor: triethylsilane for both silicon oxide and silicon nitride deposition on Float Zone silicon having a resistivity of 1-5 Ω-cm using optimized methods.

Flow rates for silicon oxide deposition were: 200 mg/min or 38.5 sccm for triethylsilane; 1000 sccm for O₂; 1000 sccm for He. The chamber pressure was 8 torr; power was 800 W. The deposition temperatures was set at 350° C.

Flow rates for silicon nitride deposition were 100 mg/min or 19.3 sccm for triethylsilane; 800 sccm for NH₃. The chamber pressure was 3 torr; power was 400 W. The deposition temperatures were set at 350 and 400° C.

The deposited passivation layer yielded a silicon device having a minority carrier lifetimes of 240 and 585 μsec, and SRV of 104 and 42.7 cm/sec; at 350 and 400° C. respectively.

The surface recombination velocity (SRV) decreaded when the deposition temperature increased from 350 to 400° C.

Since there was no measurable difference of carrier lifetime at 5e14 or 1e15, thus the minority carrier lifetime and the SRV were averaged values at 5e14 or 1e15.

While the foregoing is directed to embodiments of the present invention, other and further embodiments of the invention may be devised without departing from the basic scope thereof, and the scope thereof is determined by the claims that follow.

1. A method for depositing at least one passivation layer on a photovoltaic cell in a chamber comprising steps of:
providing the photovoltaic cell having a rear surface and a front surface;
providing a first silicon precursor;
providing an oxygen source;
depositing a silicon oxide layer having a thickness ranging from 5 to 70 nm at least on one surface of the photovoltaic cell;
providing a second silicon precursor;
providing a nitrogen source; and
depositing a silicon nitride layer having a thickness ranging from 20 to 200 nm on the silicon oxide layer;
wherein the passivation layer having a thickness ranging from 25 to 600 nm comprising at least one bi-layer comprising the silicon oxide layer and the silicon nitride layer.

2. The method of claim 1, wherein
the first silicon precursor is selected from family of SiRₓH_{y}; and
the second silicon precursor is selected from silane, the family of SiRₓH_{y}, and combinations thereof;
wherein x+y=4, y≠4, and
R is independently selected from the group consisting of
C1-C8 linear alkyl, wherein the ligand is saturated or unsaturated;
C1-C8 branched alkyl, wherein the ligand may be saturated or unsaturated;
C1-C8 cyclic alkyl, wherein the ligand may be saturated, unsaturated, or aromatic; and
NR*₃;
wherein R* can be independently selected from the group consisting of hydrogen; and linear, branched, cyclic, saturated, or unsaturated alkyl;

3. The method of claim 2, wherein
the C1-C8 linear alkyl is selected from the group consisting of methyl, ethyl, butyl, propyl, hexyl, ethylene, vinyl, allyl, 1-butylene, and 2-butylene;
the C1-C8 branched alkyl is selected from the group consisting of isopropyl, isopropylene, isobutyl, and tert-butyl;
the C1-C8 cyclic alkyl is selected from the group consisting of cyclopentyl, cyclohexyl, benzyl, and methylcyclopentyl.

4. The method of claim 1, wherein the family of SiRₓH_{y} is selected from the group consisting of: methylsilane, dimethylsilane, trimethylsilane, tetramethylsilane, ethylsilane, diethylsilane, tetraethylsilane, propylsilane, dipropylsilane, isobutylsilane, tertbutylsilane, dibutylsilane, methylethylsilane, dimethyldiethylsilane, methyltriethylsilane, ethyltrimethylsilane, isopropylsilane, diisopropylsilane, triisopropylsilane, disopropylaminosilane, aminosilane, diaminosilane, methylaminosilane, ethylaminosilane, diethylaminosilane, dimethylaminosilane, bis-tertbutylaminosilane, and bis-isopropylamino(methylvinylsilane); and combinations thereof.

5. The method of claim 1, wherein the first silicon precursor is tetramethyl silane and the second silicon precursor is trimethyl silane.

6. The method of claim 1, wherein the first silicon precursor and the second silicon precursor are the same.

7. The method of claim 5, wherein the first silicon precursor and the second silicon precursor are both triethylsilane.

8. The method of claim 1 wherein the oxygen source is selected from the group consisting of O₂, N₂O, ozone, hydrogen peroxide, NO, NO₂, N₂O₄, and mixtures thereof; and the nitrogen source is selected from the group consisting of ammonia, methylamine, dimethylamine, trimethylamine, and mixtures thereof.

9. The method of claim 1, wherein depositing method is chemical vapor deposition or plasma enhanced chemical vapor deposition.

10. The method of claim 1, wherein the oxygen source and the nitrogen source flowing at a rate independently from 500 to 10,000 sccm into the chamber; the first silicon precursor and the second silicon precursor flowing at a rate independently from 10 sccm to 1700 sccm into the chamber

11. The method of claim 1, wherein the silicon oxide layer is deposited at a temperature between 200 and 400° C.; and the silicon nitride layer is deposited at a temperature between 300° C. and 450° C.

12. The method of claim 1, wherein the passivation layer has a surface recombination velocity <200 cm/s.

13. The method of claim 1, wherein the passivation layer has a surface recombination velocity <100 cm/s.

14. The method of claim 1 further comprising a step of heat treating the passivation layer at 800 to 950° C. for 1-10 seconds.

15. The method of claim 1, wherein the silicon oxide layer having a thickness ranging from 5 to 45 nm; and the silicon nitride layer having a thickness ranging from 30 to 150 nm.

16. A photovoltaic device comprising:
a photovoltaic cell comprising:
a P-doped silicon layer adjacent a N-doped silicon layer,
a rear surface and a front surface;
and
at least one passivation layer deposited on the photovoltaic cell by the method of claim 1.

17. A photovoltaic device comprising:
a photovoltaic cell comprising
a P-doped silicon layer adjacent a N-doped silicon layer,
a rear surface and a front surface;
and
at least one passivation layer having a thickness ranging from 25 to 600 nm deposited on at least one of the surfaces of the photovoltaic cell;
wherein the passivation layer having at least one bi-layer consisting of a silicon oxide layer having a thickness ranging from 5 to 70 nm and a silicon nitride layer having a thickness ranging from 20 to 200 nm.

18. The photovoltaic device of claim 17, wherein the passivation layer has a surface recombination velocity <200 cm/s.

19. The photovoltaic device of claim 17, wherein the passivation layer has a surface recombination velocity <100 cm/s.

20. The photovoltaic device of claim 17, wherein the silicon oxide layer having a thickness ranging from 5 to 45 nm; and the silicon nitride layer having a thickness ranging from 30 to 150 nm.
